(19) United States
(12) Patent Application Publication
(10) Pub. No.: US 2009/0267448 A1
(43) Pub. Date: Oct. 29, 2009

(54) DEVICE FOR MIXING FLUIDS

(75) Inventor: Tai-Hsu Chou, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/331,480

(22) Filed: Dec. 10, 2008

(30) Foreign Application Priority Data
Apr. 25, 2008 (CN) 200810301313.5

(51) Int. Cl. H01L 41/00

(52) U.S. Cl. 310/313 R

(57) ABSTRACT

A device for mixing fluids includes a substrate, a first and a second surface acoustic wave-generating members, and fluid-receiving members. The first and second surface acoustic wave-generating members are positioned on the substrate at opposite ends. The fluid-receiving members are positioned on the substrate and between the first and second surface acoustic wave-generating members. Each fluid-receiving member includes a fixed end and a free end opposite to the fixed end. The fixed end is positioned on the substrate. A groove is defined in the free end and configured to receive the fluids.

### BACKGROUND

1. Technical Field

The disclosure relates to a device for mixing fluids.

2. Description of Related Art

In biochemical analyses or chemical reactions, mixing at least two types of microscale fluids are generally required.

An ultrasonic micromixer for microfluidic system is disclosed in, Micro Electro Mechanical Systems, 2000. MEMS 2000, 23-27 Jan. 2000, Pages 80-85. The ultrasonic micromixer applies ultrasonic vibration to mix microscale fluids in a chamber. However, the microscale fluids must flow from long micro-passages into the chamber, which prolongs mixing time.

Therefore, a new device for mixing fluids is desired to overcome the above-described shortcoming.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a perspective view of one embodiment of a device for mixing fluids.

FIG. 2 is a cross-sectional view of the device of FIG. 1, taken along line II-II.

FIG. 3 is a cross-sectional view of another embodiment of a device for mixing fluids.

### DETAILED DESCRIPTION OF THE EMBODIMENTS

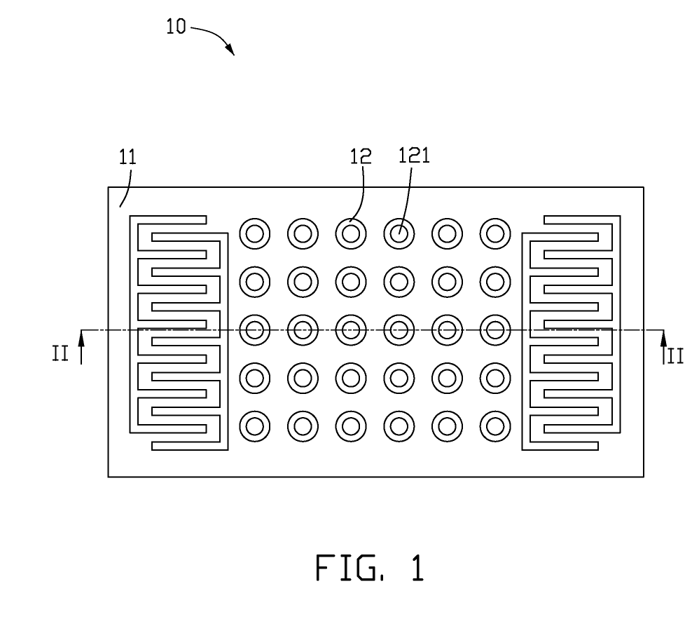

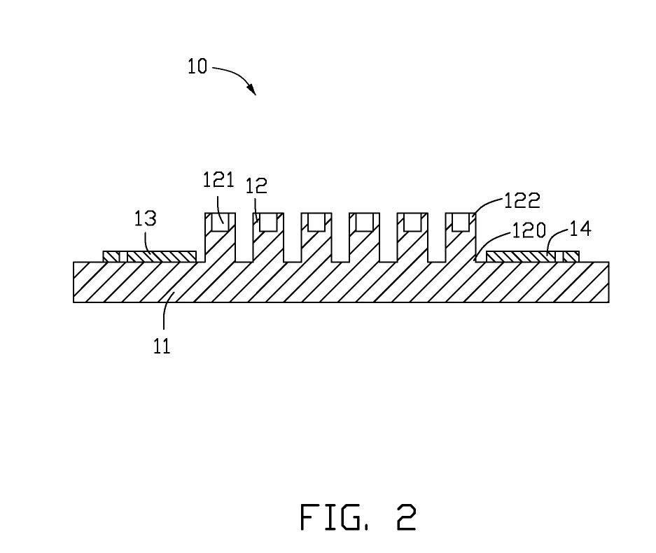

Referring to FIGS. 1 and 2, one embodiment of a device 10 for mixing fluids includes a substrate 11, a plurality of fluid-receiving members 12, a first surface acoustic wave-generating member 13 and a second surface acoustic wave-generating member 14. The first and second surface acoustic wave-generating members 13, 14 are positioned at opposite ends of the substrate 11. The fluid-receiving members 12 are positioned on the substrate 11 and between the first and second surface acoustic wave-generating members 13, 14.

The substrate 11 may be substantially rectangular shaped and made of piezoelectrical materials, such as lithium niobate (LiNbO₃), lithium tantalate (LiTaO₃), or quartz.

The fluid-receiving members 12 may be rod-shaped. The fluid-receiving members 12 are substantially perpendicularly positioned on the substrate 11 and arranged in a matrix arrangement. Each fluid-receiving member 12 includes a fixed end 120 and a free end 122 opposite to the fixed end 120. The fixed end 120 is fixed to the substrate 11. A groove 121 is defined in the free end 122 to receive fluids. The fluid-receiving members 12 may be made of piezoelectrical materials, metal materials, or metal oxide materials. In one embodiment, the fluid-receiving members 12 may be crystal rods.

The first and second surface acoustic wave-generating members 13, 14 may be interdigital transducers. Each of the first and second surface acoustic wave-generating members 13, 14 includes two interlocking comb-shaped electrodes (not labeled).

In use, the first surface acoustic wave-generating member 13 is powered, and then converts electrical signals to surface acoustic waves. The surface acoustic waves are then transmitted across the substrate 11 and to the second surface acoustic wave-generating member 14. As the surface acoustic waves are transmitted across the substrate 11, some surface acoustic waves are lapped thereby generating resonance. Fluids received in the grooves 121 are immediately mixed together by the resonance.

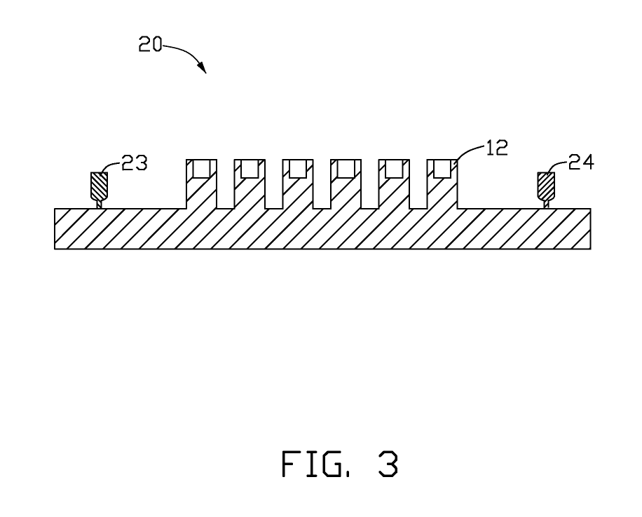

Referring to FIG. 3, another embodiment of a device 20 for mixing fluids is similar to the device 10 of FIGS. 1 and 2, except that each of the first and second surface acoustic wave-generating members 23, 24 may be surface acoustic probes. The surface acoustic probes 23, 24 generate surface acoustic waves. The fluid-receiving members 12 are positioned between the first and second surface acoustic wave-generating members 23, 24.

It is believed that the present embodiments and their advantages will be understood from the foregoing description, and it will be apparent that various changes may be made thereto without departing from the spirit and scope of the embodiments or sacrificing all of its material advantages, the examples here before described merely being preferred or exemplary embodiments.

What is claimed is:

1. A device for mixing fluids, comprising:
a substrate;
a first surface acoustic wave-generating member positioned on the substrate;
a second surface acoustic wave-generating member positioned on the substrate at opposite ends; and
a plurality of fluid-receiving members positioned on the substrate and between the first and a second surface acoustic wave-generating members, wherein each fluid-receiving member comprises a fixed end and a free end opposite to the fixed end; the fixed end is positioned on the substrate; a groove is defined in the free end and configured to receive the fluids.

2. The device of claim 1, wherein each fluid-receiving member is rod-shaped.

3. The device of claim 2, wherein each fluid-receiving member is a crystal rod.

4. The device of claim 1, wherein the plurality of fluid-receiving members is substantially perpendicularly positioned on the substrate and arranged in a matrix arrangement.

5. The device of claim 1, wherein the plurality of fluid-receiving members is made of a material selected from the group consisting of piezoelectrical materials, metal materials, and metal oxide materials.

6. The device of claim 1, wherein the substrate is made of piezoelectrical materials.

7. The device of claim 1, wherein the substrate is substantially rectangular shaped.

8. The device of claim 1, wherein the first and second surface acoustic wave-generating members are interdigital transducers.

9. The device of claim 1, wherein the first and second surface acoustic wave-generating members are surface acoustic probes.

10. A device for mixing fluids, comprising:
a substrate;
a first interdigital transducer positioned on the substrate;
a second interdigital transducer positioned on the substrate; and
a plurality of rods positioned on the substrate and between the first and second interdigital transducer, wherein each rod comprises a fixed end and a free end opposite to the fixed end; the fixed end is positioned on the substrate; a groove is defined in the free end and configured to receive the fluids.

11. The device of claim 10, wherein each rod is a crystal rod.

12. The device of claim 10, wherein the plurality of rods is substantially perpendicularly positioned on the substrate and arranged in a matrix arrangement.

13. The device of claim 10, wherein the plurality of rods is made of a material selected from the group consisting of piezoelectrical materials, metal materials, and metal oxide materials.

14. The device of claim 10, wherein the substrate is made of piezoelectrical materials.

15. A device for mixing fluids, comprising:
a substrate;
a first surface acoustic wave probe positioned on the substrate;
a second surface acoustic wave probe positioned on the substrate; and
a plurality of rods positioned on the substrate and between the first and second surface acoustic wave probes, wherein each rod comprises a fixed end and a free end opposite to the fixed end; the fixed end is positioned on the substrate; a groove is defined in the free end and configured to receive the fluids.

16. The device of claim 15, wherein each rod is a crystal rod.

17. The device of claim 15, wherein the plurality of rods is substantially perpendicularly positioned on the substrate and arranged in a matrix arrangement.

18. The device of claim 15, wherein the plurality of rods is made of a material selected from the group comprising piezoelectrical materials, metal materials, and metal oxide materials.

19. The device of claim 15, wherein the substrate is made of piezoelectrical materials.

20. The device of claim 15, wherein the substrate is substantially rectangular shaped.
